(19) United States
(12) Patent Application Publication
(10) Pub. No.: US 2026/0317952 A1
(43) Pub. Date: Oct. 15, 2026

(54) CONTROLLED SYNTHESIS OF SEEDING NANOCRYSTALS FOR THE FABRICATION OF TRANSPARENT CONDUCTING PEROVSKITE OXIDES ON NON-EPITAXIAL SUBSTRATES

(71) Applicant: Wisconsin Alumni Research Foundation, Madison, WI (US)

(72) Inventors: Paul Gregory Evans, Madison, WI (US); Lakshmi Kumar Chinna Kannu, Madison, WI (US); Maureen Marandu, Madison, WI (US); Rui Liu, Madison, WI (US)

(21) Appl. No.: 19/176,657

(22) Filed: Apr. 11, 2025

(51) Int. Cl. C30B 29/30; C03C 17/245; C30B 29/22

(52) U.S. Cl. CPC C30B 29/30; C03C 17/245; C30B 29/22; C03C 2217/228; C03C 2217/24; C03C 2217/94; C03C 2218/154; C03C 2218/345

(57) ABSTRACT

Transparent conducting oxide (TCO) films composed of transparent, electrically conducting, perovskite oxides (TCPOs) and methods of making the films are provided. The TCPOs are crystallized from their corresponding amorphous films using embedded crystalline perovskite oxide seeds as nucleation sites. The amorphous films have the same complex oxide composition as the TCPO but are in an amorphous form. The crystalline perovskite oxide seeds are themselves formed on a substrate from a thin amorphous oxide film via coarsening. Because the seeded TCPO film formation is not based on epitaxial growth from a substrate, the lateral dimensions of the TCPO films are not limited by the size of available single-crystal epitaxial growth substrates.

### REFERENCE TO GOVERNMENT RIGHTS

This invention was made with government support under 1720415 awarded by the National Science Foundation. The government has certain rights in the invention.

### BACKGROUND

Complex oxides are often fabricated as epitaxial thin films on oxide single crystal substrates, such as SrTiO₃ and related pseudocubic perovskites, and by using oxide intermediate layers on silicon (Si) substrates. Integrating the dielectric and optical properties of perovskite oxides such as SrTiO₃ on substrates beyond single crystals of oxides and semiconductors has the potential to lead to new applications in electrooptic, radiofrequency (RF) electronics, piezoelectrics, and transparent conductors. Non-epitaxial SrTiO₃ thin films on alumina substrates, for example, have promising nonlinear dielectric properties for microwave applications (A. Turnarkin et al. Coatings 14, 3 (2024).) The processes employed to integrate oxides on non-epitaxial substrates include direct crystallization during deposition, the random crystallization of the phase of interest from a deposited amorphous thin film, or crystallization seeded by nanocrystals. Nanocrystals on SiO₂, in particular, can serve as the nucleation sites for the subsequent crystallization of SrTiO₃ or other complex oxides. (Y. Chen et al., J. Phys. Chem. C. 3, 7447-7456 (2019); A. Boileau et al., Adv. Funct. Mater. 32, 2108047 (2022); N. Yamada et al., Appl. Phys. Exp. 4, 045801 (2011).) In these cases, the crystallization of an amorphous complex oxide thin film depends on the formation and distribution of nanocrystalline seeds. In these cases, the crystallization of an amorphous complex oxide thin film depends on the formation and distribution of nanocrystalline seeds.

The formation of complex oxide thin films on non-epitaxial substrates offers the potential to expand the range of applications of transparent conducting oxides (TCOs) for electronic and optical devices and applications. Indium-doped Tin Oxide (ITO) is currently the most widely used TCO. However, indium is not abundant on earth, so the cost of ITO is high, experiences significant variability, and can be expected to continue to increase. Therefore, it would be advantageous to develop improved methods of forming TCOs, particularly with areas larger than those available using single-crystal oxide substrates, including alternatives to ITO.

### SUMMARY

Transparent conducting perovskite oxide (TCPO) films and methods for making said films are provided.

One embodiment of a TCPO film includes: a substrate; a plurality of crystalline perovskite oxide seeds on a surface of the substrate; and a crystalline film of a TCPO on the surface of the substrate between the crystalline perovskite oxide seeds. In some illustrative embodiments, the TCPO is SrNbO₃ and the perovskite oxide of the crystalline perovskite oxide seeds is BaTiO₃; in some illustrative embodiments, the TCPO is BaSnO₃ and the perovskite oxide of the crystalline perovskite oxide seeds is CaZrO₃ or BaTiO₃; and in some illustrative embodiments, the TCPO is Sr-doped LaCrO₃ and the perovskite oxide of the crystalline perovskite oxide seeds is NdAlO₃, SmAlO₃, PrAlO₃, KTaO₃, or SrTiO₃.

Another embodiment of a TCPO film includes: a substrate composed of a substrate material; a plurality of crystalline perovskite oxide seeds on a surface of the substrate, wherein a coefficient of thermal expansion of the substrate material differs from a coefficient of thermal expansion of the perovskite oxide of the perovskite oxide seeds by no more 50%; and a crystalline film of a TCPO on the surface of the substrate between the crystalline perovskite oxide seeds.

Another embodiment of a TCPO film includes: a substrate composed of a substrate material; a plurality of crystalline complex alloy perovskite oxide seeds on a surface of the substrate; and a crystalline film of a TCPO on the surface of the substrate between the crystalline complex alloy perovskite oxide seeds, wherein a lattice constant of the crystalline complex alloy perovskite oxide and a lattice constant of the TCPO differ by less than 0.1 Å. In some illustrative embodiments, the complex alloy perovskite oxide is a (Ba,Sr)TiO₃ complex alloy and the transparent conducting perovskite oxide is SrVO₃, Sr-doped LaCrO₃, SrNbO₃, or BaSnO₃; and in some illustrative embodiments the complex alloy perovskite oxide is a (Ca,Sr)RuO₃ complex alloy and the transparent conducting perovskite oxide is SrVO₃, or Sr-doped LaCrO₃.

One embodiment of a method of forming a transparent conducting perovskite oxide film includes the steps of: forming a continuous amorphous thin film of a perovskite oxide precursor on a surface of a substrate via sputter deposition without the use of a mask, the thin film having a uniform thickness in the range from 0.3 nm to 15 nm; converting the continuous amorphous thin film into an array of crystalline perovskite oxide seeds via a thermal anneal; depositing a layer of amorphous complex oxide on the surface of the substrate around the crystalline perovskite oxide seeds; and heating the layer of amorphous complex oxide, whereby the layer of amorphous complex oxide is laterally crystallized from the crystalline perovskite oxide seeds to form the transparent conducting perovskite oxide film. In some illustrative embodiments, the perovskite oxide of the crystalline perovskite oxide seeds is SrTiO₃, NdAlO₃, SmAlO₃, CaTiO₃, PrAlO₃, KTaO₃, YAlO₃, or Ce:YAP and the transparent conducting perovskite oxide is SrVO₃; and in some illustrative embodiments, the perovskite oxide of the crystalline perovskite oxide seeds is SrTiO₃, NdAlO₃, SmAlO₃, PrAlO₃, or KTaO₃ and the transparent conducting perovskite oxide is Sr-doped LaCrO₃.

Other principal features and advantages of the invention will become apparent to those skilled in the art upon review of the following drawings, the detailed description, and the appended claims.

### BRIEF DESCRIPTION OF THE DRAWINGS

Illustrative embodiments of the invention will hereafter be described with reference to the accompanying drawings, wherein like numerals denote like elements.

FIGS. 1A and 1B. Schematic illustrations of a polycrystalline perovskite oxide seed with (FIG. 1A) and without (FIG. 1B) curvature and delamination (“curling”).

FIGS. 2A-2D. FIGS. 2A-2B show scanning electron microscopy (SEM) images of SrTiO₃ nanocrystals (“nanoseeds”) formed by heating initially amorphous SrTiO₃ thin films with average deposited amorphous layer thicknesses from 9.2 and 10.3 nm, resulting in seeds covering surface with area fractions of (FIG. 2A) 0.04 and (FIG. 2B) 0.56 for 2 h. FIG. 2C shows the mean radius of nanocrystals, R, as a function of the average area fraction of the surface SrTiO₃ before heating. FIG. 2D shows area density of SrTiO₃ covered by nanocrystals.

FIGS. 3A-3E. FIGS. 3A-3B show SEM images of nanocrystals created by depositing an amorphous SrTiO₃ thin film with a thickness of 9.4 nm and heating durations t of (FIG. 3A) 15 min and (FIG. 3B) 2 h. FIG. 3C shows the mean radius of nanocrystals, R̅, as a function of heating time. FIG. 3D shows area density of nanocrystals as a function of heating time. FIG. 3E shows average nanocrystal height as a function of the heating time.

FIG. 4 shows an X-ray diffraction pattern of SrTiO₃ nanocrystals on a SiO₂/Si substrate, acquired with an x-ray wavelength of 1.542 Å. The detector was fixed at a 2θ angle of 35°. Vertical lines are labeled with the indices of families of x-ray reflections of SrTiO₃.

FIGS. 5A-5B. FIG. 5A shows a comparison of the Ostwald ripening model (line) with the time dependence of the mean radius from FIG. 3C (points). The line corresponds to t^{0.29}. FIG. 5B shows area density as a function of time. The line shows the best fit of the data, with a line proportional to t^{-0.78}.

FIGS. 6A-6B. SEM images of crystalline SrVO₃ films nucleated from SrTiO₃ seeds on a silicon (FIG. 6A) and a fused quartz (FIG. 6B) substrate.

### DETAILED DESCRIPTION

TCO films composed of transparent, electrically conducting, TCPOs and methods of making the films are provided. The TCPO films and methods are based on a detailed understanding of the TCPO crystallization process and on novel combinations of growth substrates, seed crystals, and TCPOs. The novel combinations expand the TCO compositions available for a wide range of applications that require TCOs with different electronic and optical properties. The TCPO films can be used as conductive layers in liquid crystal displays, infrared-blocking layers in architectural and industrial glass, as contacts in photovoltaic devices, and other in other devices.

Perovskite oxides are materials having the general formula ABO₃, where A and B represent metal cations, and typically the A cations are larger than the B cations. The perovskite oxides can be doped, such that they include two different large metal cations. Thus, for doped perovskite oxides, the “A” and/or “B” sites (or both) in the perovskite formula can represent two or more different metal cations. The doped perovskite oxides are also referred to herein as complex alloy perovskite oxides. Transparent electrically conductive perovskite oxides are characterized by a high electrical conductivity and optical transparency in the visible, infrared (IR), and/or ultraviolet (UV) regions of the electromagnetic spectrum. By way of illustration, TCPOs may have electrical conductivities at room temperature (23° C.) of 100 S cm⁻¹ or higher, including electrical conductivities of 10⁵ S cm⁻¹ or higher.

The TCPOs are crystallized from their corresponding amorphous films using embedded crystalline perovskite oxide seeds as nucleation sites. The amorphous films have the same complex oxide composition as the TCPO but are in an amorphous form. The crystalline perovskite oxide seeds are themselves formed on a substrate from a thin amorphous oxide film via coarsening from their own corresponding complex oxide. Because the seeded TCPO film formation is not based on epitaxial growth from a substrate, the lateral dimensions of the TCPO films are not limited by the size of available single-crystal epitaxial growth substrates, which often have growth surface dimensions on the scale of only one to a few square centimeters. Rather, using the methods described herein, crystalline TCPO films having lateral surface areas of 1 m² or larger can be formed.

Aspects of the inventions described herein are based on the inventors' discovery that the evolution of perovskite oxide seed crystals from an amorphous thin film on a substrate can be accurately predicted using a coarsening model, based on Ostwald ripening, as illustrated in the Examples. Using this model, appropriate crystalline seed ripening conditions, including appropriate amorphous oxide film thicknesses, can be identified to enable the fabrication of an array of crystalline seeds from an amorphous oxide film having a uniform thickness. The model eliminates the need to deposit the amorphous oxide through a mask to form a film having a thickness gradient, as has been proposed previously (U.S. Pat. No. 12,074,235). This simplifies the seed fabrication process and facilitates the formation of seed arrays over large surface areas. Additionally, the coarsening model can be used to identify thermal annealing temperatures and times that provide seeds having a mean radius and seed density appropriate for the nucleation of a variety of TCPOs.

The crystalline TCPO films are made by forming an amorphous layer of complex oxide having the same composition as the TCPO around a plurality of nanoscale, crystalline, perovskite oxide seeds, and subsequently thermally annealing the amorphous complex oxide. When the annealing step is conducted at a sufficiently low temperature, the film growth kinetics will favor lateral TCPO crystallization outward from the perovskite oxide seeds over competing unfavorable processes including: (i) homogeneous TCPO crystal nucleation within the amorphous layer of TCPO; (ii) high-temperature reactions with the substrate or perovskite oxide seed crystals; (iii) decomposition of the TCPO into gas-phase components; and (iv) the formation of crystals in a structural phase, composition, or metal oxidation state different from the intended TCPO compound. As a result, the layer of amorphous complex oxide can be converted into a crystalline TCPO film composed of large crystalline TCPO grains. These grains can be large (i.e. “single crystalline”) or can be a small fraction of the spacing of the seeds. The resulting TCPO films can thus be polycrystalline, even after the elimination of unfavorable processes (i) to (iv). The polycrystallinity is suitable for applications of TCPOs.

The seed crystals, which act as nucleation sites for the TCPO crystallization, are formed directly on the surface of a substrate by depositing a continuous thin film of the amorphous oxide on the surface of a substrate and converting the amorphous film into an array of seeds via ripening and crystallization. The amorphous oxide has the same composition as the perovskite oxide seed crystals formed therefrom but is in an amorphous form. Thus, the amorphous oxide that is converted into a crystalline perovskite oxide is referred to herein as a perovskite oxide precursor. The deposition of the thin amorphous oxide film can be carried out using, for example, sputtering. While the precise positional distribution of the seeds in the array will be random, the mean seed radius and density on the substrate can be controlled during the thermal anneal of the amorphous film, as discussed above, and illustrated in Example 1. The seed crystals have nanoscale dimensions and, therefore, can be referred to as “nanocrystal seeds” or simply “nanoseeds.” As used herein, the term nanoscale refers to a largest lateral dimension, such as a diameter, that is smaller than 1 μm and, more typically, smaller than 500 nm (e.g., in the range from 50 nm to 500 nm, including in the range from 100 nm to 300 nm). The thickness of the nanoseeds is generally much smaller than their diameter, typically no greater than 4 nm. For example, in some embodiments of the nanoseed arrays, the nanoseeds have a thickness in the range from 0.5 nm to 4 nm.

Once the crystalline perovskite oxide seeds are formed on a substrate, an amorphous complex oxide film is deposited so that the amorphous material contacts the pre-formed seeds. The amorphous materials may, for example, be deposited between and optionally, over the seeds. This amorphous film is heated to induce crystallization. The crystallization proceeds outwardly from the seeds at an expanding crystal/amorphous growth front. Provided that the annealing temperature is sufficiently low, the kinetics of crystallization will favor lateral crystal growth initiated at the crystalline seeds rather than homogeneous nucleation within the amorphous layer at locations away from the seeds. As a result, lateral crystal growth from the seeds can continue over lengths of 1 μm or greater before the growing crystals impinge on crystals grown from neighboring seeds or crystals grown via homogeneous nucleation at locations away from the seeds. Crystal growth may continue until the growing crystals have merged into a continuous polycrystalline TCPO film or may be discontinued earlier to provide a film comprising isolated TCPO crystal grains surrounded by an amorphous TCPO matrix. The thickness of the amorphous complex oxide film and the crystalline TCPO film crystallized therefrom can be less than, equal to, or greater than that of the crystalline seeds. Thus, the TCPO film may be present only between the seeds or may fully or completely cover the seeds.

The temperature at which the lateral crystallization of the TCPO is favored over homogenous nucleation originating at a location away from a perovskite oxide seed may vary depending upon the structure and composition of the TCPO being crystallized. However, the temperature can be lower than 500° C. and, more typically, lower than 470° C. Depending on the composition of the TCPO, even at these low temperatures, reasonable growth rates can be achieved; for example, growth rates of at least 0.5 nm/min, at least 0.7 nm/min, or at least 1 nm/min can be achieved.

Phase-pure cubic strontium vanadate SrVO₃ films are an example of TCPO films that can be crystallized directly from their corresponding amorphous films using the methods described herein by carrying out the crystallization in a reducing atmosphere. This is significant because strontium vanadium oxide compounds can exist in many phases, but for TCO applications the cubic SrV⁴⁺O₃ phase is desired, as it is highly electrically conducting. The ability to crystallize a phase-pure SrV⁴⁺O₃ directly on the substrate eliminates additional processing steps that are needed to convert other undesirable phases, such as the non-conducting triclinic Sr₂V₂⁵⁺O₇ phase, into the phase cubic SrV⁴⁺O₃. For example, post-crystallization of unwanted phases using a heat treatment in a gas environment having an oxygen activity that promotes the reduction of the vanadium to a lower oxidation state is not needed.

The methods are not limited to the formation of SrVO₃ films. The discovery that perovskite oxide film thickness and the thermal conditions used to crystallize an amorphous perovskite oxide film and ripen the seeds to appropriate sizes and densities can be applied to form a variety of TCPO films with improved optical and electronic properties. This is advantageous because, while SrVO₃ is an attractive alternative to ITO for many applications, there are some limits to the range of applicability of SrVO₃. For example, as discussed above, care must be taken to crystallize strontium vanadate in the right phase and oxidation state to achieve an electronically conducting and optically transparent film. Moreover, while SrVO₃ is transparent in the visible region of the electromagnetic spectrum, other TCPOs may be desirable depending on the application. SrVO₃, for example, has poor transparency in the ultraviolet region. Other TCPOs that can be nucleated as crystalline films from perovskite oxide seeds include, but are not limited to, SrNbO₃, BaSnO₃, Sr-doped LaCrO₃ (i.e., (La,Sr)CrO₃, where the Sr fraction is between 0.04 and 0.5, such as La_{0.75}Sr_{0.25}CrO₃; see K. H. L. Zhang et al. Adv. Mater. 27, 5191-5195 (2015).)

Generally, it is advantageous for the seed crystals embedded in a crystallized TCPO film to be small with a large seed spacing because more and larger seed crystals reduce the optical transparency of the film. However, a higher spacing between the seed crystals can increase the defect density in the crystallized TCPO films, which can impair the electrical conductivity and/or optical properties of the TCPO films. As shown in Example 1 below, as the thickness of an amorphous perovskite oxide film is increased, the packing of the seed crystals in the seed array made therefrom increases, and as the film annealing time increases, the average radius of the seed crystals in the array increases, while the area density of the seed crystals on the substrate surface decreases, consistent with an Ostwald ripening model. Using this knowledge, one can identify film thickness and annealing times that will produce a distribution of seed crystals suitable for the formation of a given TCPO film. By way of illustration, large-area crystalline SrVO₃ films with electrical properties equivalent to or better than ITO with the same thickness can be formed using SrTiO₃ seed crystal arrays having a seed crystal area density in the range from 1.9 μm⁻² to 9 μm⁻² (with corresponding seed crystal radii ranging from 55 nm to 200 nm). Said seed crystals can be ripened from an amorphous SrTiO₃ film having a thickness in the range from 9 nm to 10 nm at annealing times in the range from 15 min to 2 h and an annealing temperature of 650° C. However, seed arrays with an area density outside of this range can be fabricated, including seed arrays having an area density in the range from 0.15 μm⁻² to 1000 μm⁻² (with corresponding average seed crystal radius of less than 10 nm).

Because the perovskite oxide seed crystals and TCPO films are not grown epitaxially on a growth substrate with which the perovskite oxides and TCPO must be closely lattice matched at the time of nucleation, the substrates on which the seed crystals and TCPO films can be formed are not particularly limited, and include single crystal substrates, polycrystalline substrates, amorphous substrates, and organic polymer substrates (i.e., plastic substrates). In some embodiments, crystalline SrVO₃ films or films of other TCPOs as described herein are formed on a silicon dioxide substrate, a silicon substrate, or a quartz substrate. However, other substrates can be used, as discussed in more detail below. Examples of alternative substrate materials include borosilicate glasses, such as D263 available from SCHOTT AG, sapphire, mica, aluminosilicate glass, such as AF37 available from Prazisions Glas & Optik Gmbh.

The perovskite seed crystals have a different chemical composition than the crystalline TCPO films that are nucleated therefrom. However, the perovskite oxide and TCPO should contain structural subunits within their crystal structures that are sufficiently similar to enable the seed-nucleated crystallization of the TCPO. Thus, it is desirable for the TCPO and the perovskite oxide of the seed crystals to be closely lattice matched to crystallize a high-quality crystalline TCPO film. Additionally, the crystal symmetry (structure) of the perovskite oxide seed crystal can be selected to provide a TCPO film having the same symmetry. Table 1 provides an illustrative list of perovskite oxide/TCPO pairs that may be used as the seed crystal and TCPO film materials.

TABLE 1

| Perovskite | Lattice | Crystal | | |
|---|---|---|---|---|
| Oxide | Parameter | Structure of | | Lattice |
| (Seed | of Perovskite | Perovskite | | Parameter of |
| Crystal) | Oxide (Å) | Oxide | TCPO | TCPO (Å) |
| SrTiO₃ | 3.905 | cubic | SrVO₃ | 3.842 |
| | | | Sr-doped LaCrO₃ | 3.876 |
| | | | (La_{0.75}Sr_{0.25}CrO₃) | |
| NdAlO₃ | 3.84 | pseudocubic | SrVO₃ | 3.842 |
| | | | Sr-doped LaCrO₃ | 3.876 |
| | | | (La_{0.75}Sr_{0.25}CrO₃) | |
| SmAlO₃ | 3.83 | pseudocubic | SrVO₃ | 3.842 |
| | | | Sr-doped LaCrO₃ | 3.876 |
| | | | (La_{0.75}Sr_{0.25}CrO₃) | |
| CaTiO₃ | 3.74 | pseudocubic | SrVO₃ | 3.842 |
| PrAlO₃ | 3.81 | pseudocubic | SrVO₃ | 3.842 |
| | | | Sr-doped LaCrO₃ | 3.876 |
| | | | (La_{0.75}Sr_{0.25}CrO₃) | |
| BaTiO₃ | 4.01 | cubic or | SrNbO₃ | 4.023 |
| | | tetragonal | BaSnO₃ | 4.116 |
| KTaO₃ | 3.89 | cubic | SrVO₃ | 3.842 |
| | | | Sr-doped LaCrO₃ | 3.876 |
| | | | (La_{0.75}Sr_{0.25}CrO₃) | |
| YAlO₃ | 3.73 | cubic | SrVO₃ | 3.842 |
| Cerium- | 3.697 | pseudocubic | SrVO₃ | 3.842 |
| doped | | | | |
| Yttrium | | | | |
| Aluminum | | | | |
| Perovskite | | | | |
| (Ce:YAP) | | | | |
| CaZrO₃ | 4.16 | pseudocubic | BaSnO₃ | 4.116 |

(See M. Marezio, P. D. Dernier, and J. P. Remeika. J. Solid State Chem. 4, 11-19 (1972); V. V. Lemanov et al., Solid State Commun. 110 611-614 (1999); and C.-S. Woo et al., Phys. Rev. B 86 054417 (2012).)

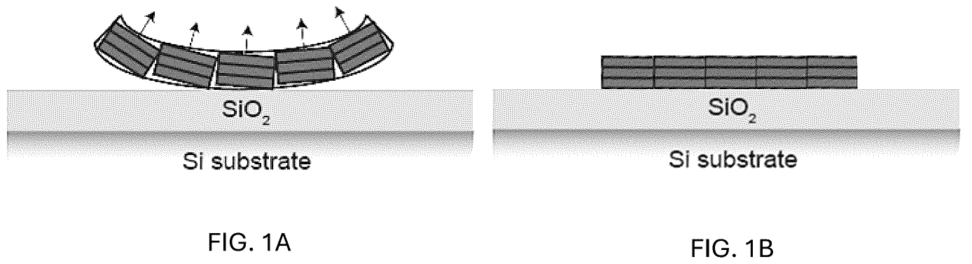

Arrays of SrTiO₃ seed crystals have been proposed previously for the formation vanadate perovskite films (U.S. Pat. No. 12,074,235). However, differences in the coefficients of thermal expansion (CTE) of the SrTiO₃ and the vanadate perovskites lead to curvature in the seed crystals during the thermal annealing, whereby the edges of the seed crystal curl upward, away from the substrate. As a result, the edges of the seed crystals are raised above the substrate surface and are higher than the center of the seed crystals. This edge-curling can be eliminated by using perovskite oxide seeds having a CTE that is the same as, or close to, that of the substrate upon which the perovskite oxide seeds are formed. By way of illustration, in some material systems the edge-curling is eliminated by selecting a substrate material having a CTE that differs from the CTE of the perovskite oxide of the seeds by no more than 50%. This includes embodiments in which the substrate material has a CTE that differs from the CTE of the perovskite oxide of the seeds by no more than 10%, further includes embodiments in which the substrate material has a CTE that differs from the CTE of the perovskite oxide of the seeds by no more than 5%, still further includes embodiments in which the substrate material has a CTE that differs from the CTE of the perovskite oxide of the seeds by no more than 1%. As a result, the seed crystals lay flat and are in contact with the substrate across their lateral dimensions (e.g., radius). This effect is shown schematically in FIGS. 1A and 1B, for seeds with (FIG. 1A) and without (FIG. 1B) curling.

Table 2 lists several substrate/perovskite oxide seed materials that are particularly well matched based on their TCEs.

TABLE 2

| | CTE of | | CTE of |
|---|---|---|---|
| Perovskite Oxide | Perovskite Oxide | | Substrate |
| (Seed Crystal) | (K⁻¹) | Substrate Material | Material (K⁻¹) |
| CaZrO₃ | 1 × 10⁻⁶ | D263 Borosilicate | 1 × 10⁻⁶ |
| | | Glass | |
| CaZrO₃ | 1 × 10⁻⁶ | Cordierite | (0.05-1.5) × 10⁻⁶ |
| | | (2MgO•2Al₂O₃•5SiO₂) | |
| Ce:YAP | (2.32-8.7) × 10⁻⁶ | D263 Borosilicate | 1 × 10⁻⁶ |
| | | Glass | |
| Ca(Zr, Hf, Ti)O₃ | (0.84-1.2) × 10⁻⁵ | Polycrystalline | (0.63-0.94) × 10⁻⁶ |
| | | Al₂O₃ | |
| (La, Sr)(Fe, Co)O₃ | (1.5-2.5) × 10⁻⁵ | Polycrystalline | 1.05 × 10⁻⁵ |
| | | ZrO₂ | |

Alternatively, the perovskite oxide of the seed crystal can be formed with a specific composition within a continuous range of alloy compositions, “doped,” to reduce or eliminate seed crystal curling and/or to provide a lattice constant matching the TCPO. Lattice constant matching is facilitated by the selection of the lattice parameter based on the composition of the alloys in a complex alloy perovskite oxide. Using this lattice matching approach, the composition of the complex alloy perovskite oxide of the crystalline seed can be tailored such that its lattice constant differs from the lattice constant of the TCPO by less than 0.1 Å. This includes embodiments in which the lattice constant of the complex alloy perovskite oxide of the crystalline seed differs from that of the TCPO by less than 0.07 Å, less than 0.05 Å, and less than 0.02 Å, and further includes perfect lattice matching between the lattice constant of the complex alloy perovskite oxide of the crystalline seed the TCPO. For example, alloys of BaTiO₃ and SrTiO₃, termed (Ba,Sr)TiO₃; a complex alloy perovskite oxide having Ba and Sr atoms at the A site), have pseudocubic lattice parameters continuously and smoothly ranging from 3.90 Å to 3.98 Å for Ba fractions up to 70% (M. McQuarrie, J. Am. Ceram. Soc. 38, 444 (1955)). Similarly, alloys of CaRuO₃ and SrRuO₃, (Ca,Sr)RuO₃, have lattice parameters ranging from 3.84 Å to 3.90 Å (Z. R. Dai et al., Mater. Res. Bull. 34, 6 933-942 (1999)).

Similarly, the coefficient of thermal expansion for complex oxide alloys varies significantly as a function of the composition. The thermal conductivity in the alloys of La, Sr on the A site Fe and Co on the B site of ABO₃ varies from 1.5×10⁻⁵ to 2.5×10⁻⁵ (S. Taniguchi and M. Aniya, J. Phys. Soc. Jpn. Suppl. A 79, 106 (2010)). The coefficient of thermal expansions of the end members of the Ca(Zr, Hf, Ti)O₃ system, CaZrO₃, CaTiO₃, and CaHfO₃, have thermal expansion coefficients that range from 8.4×10⁻⁶ to 1.2×10⁻⁵ (H. Yang et al., J. Alloys Compounds 504, 201-204 (2010)). These and other metal oxide alloys provide the means to fine-tune the coefficient of thermal expansion mismatch between the seeds and the substrate.

### Examples

Example 1: This example illustrates the formation of perovskite oxide seed crystals from an amorphous perovskite oxide film with controlled seed crystal sizes and densities.

Nanocrystals were formed from amorphous SrTiO₃ thin films with average thicknesses in the sub-nm to nm range. The amorphous SrTiO₃ layers were deposited by radiofrequency (RF) sputtering onto oxidized Si substrates. The deposition system was initially evacuated to a pressure of 2×10⁻⁶ Torr, followed by the introduction of a 13:6 Ar:O₂ gas mixture at a total pressure of 19 mTorr. The SiO₂/Si substrates were not intentionally heated during deposition. The sputter deposition source employed a SrTiO₃ target using an RF power of 30 W. SEM micrographs were analyzed to calculate the fraction of the surface area covered by nanocrystals. The average height of the nanocrystals was measured using non-contact atomic force microscopy (AFM). Amorphous SrTiO₃ layers with thicknesses from 9 to 11 nm were produced by varying the deposition time. The SrTiO₃ layers were heated in air at atmospheric pressure at 650° C. for up to 2 h. The distribution of the sizes of the nanocrystals was determined by assuming that SrTiO₃ nanocrystals are approximately circular and measuring the radii of a large numbers of nanocrystals using SEM. The mean radius R̅ of the SrTiO₃ nanocrystals is calculated as the sum of the individual radii Ri of all measured nanocrystals, divided by the number of measured nanocrystals N. The area density of the nanocrystals is defined as the number of nanocrystals per unit area.

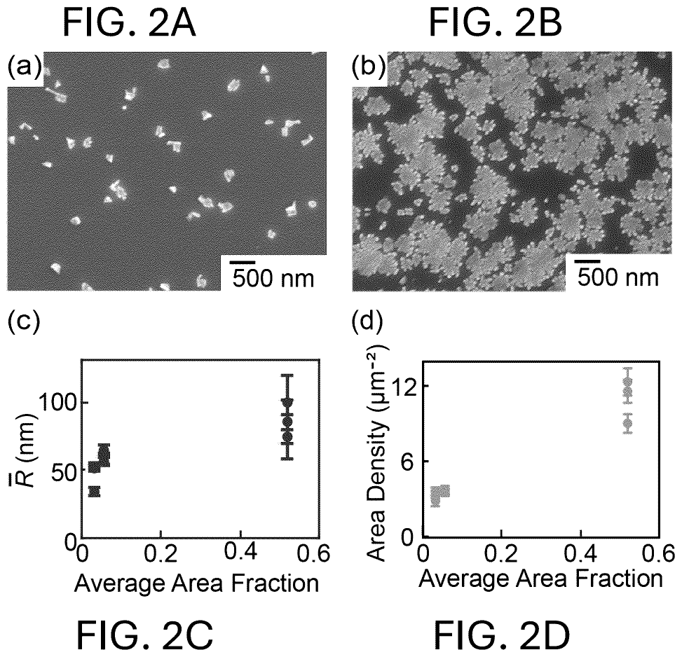

FIGS. 2A and 2B show SEM micrographs of SrTiO₃ nanocrystals formed by heating amorphous layers for 2 h to produce nanocrystals covering the surface with area fractions of 0.04 and 0.56. For both average thicknesses, there were exposed regions of the substrate between the nanocrystals. The size of the nanocrystals increased with increased area fraction. FIG. 2C shows the mean radius of the nanocrystals as a function of the average area fraction. The area density for these two is plotted in FIG. 2D. The area density was smaller at lower area fraction.

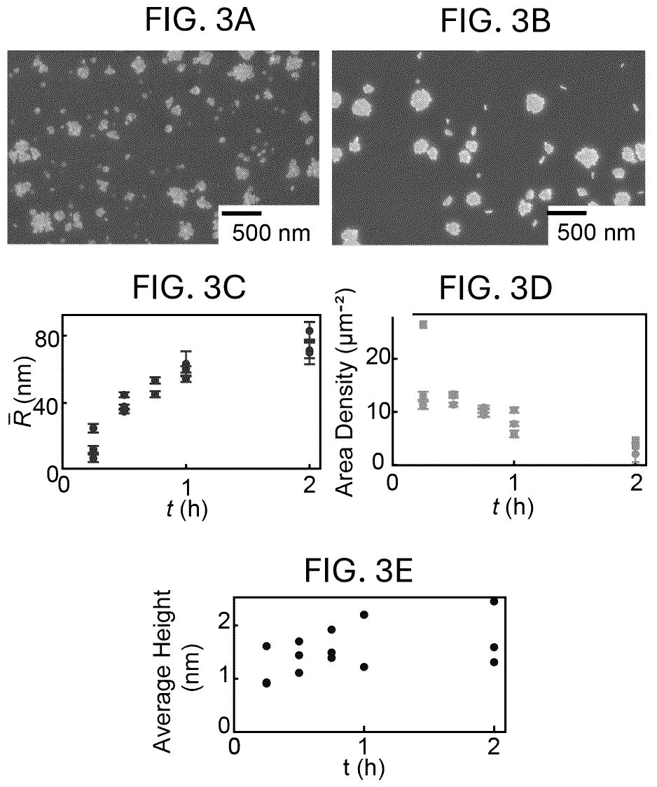

FIGS. 3A and 3B show SEM images of nanocrystals formed by heating an amorphous SrTiO₃ thin film with an average thickness of 9.4 nm for durations of 15 min and 2 h. Many smaller nanocrystals were observed after 15 min, as shown in FIG. 3A. The radius of the nanocrystals increased with longer heating times, as seen in the SEM image acquired after 2 h, FIG. 3B. The mean radius as a function of heating time t is shown in FIG. 2C. The growth in the mean nanocrystal radius was accompanied by a decrease in area density, as shown in FIG. 3D. FIGS. 3C and 3D include multiple measurements at different locations on the surface with each corresponding heating duration. The uncertainties plotted in both figures, FIGS. 3C and 3D, were determined using the variances of each measurement. FIG. 3E shows the average height of nanocrystals as a function of the heating time. The height of the SrTiO₃ nanocrystals did not exhibit a systematic change as a function of heating time. The calculation of the average thickness above used an average height of 2 nm.

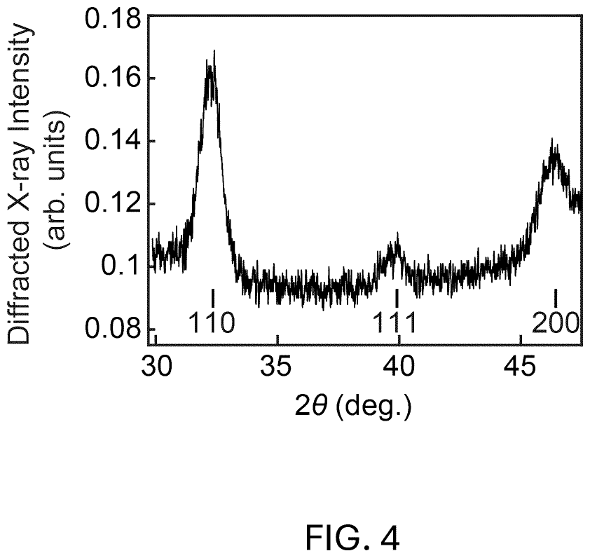

An x-ray diffraction pattern of SrTiO₃ nanocrystals resulting from heating an amorphous layer with a deposited thickness of 10.3 nm on a SiO₂/Si substrate for 2 h is shown in FIG. 4. These crystals covered the surface with an area fraction 0.56. The diffraction pattern was acquired using a grazing incidence geometry with an x-ray incidence angle of 3° and an x-ray wavelength of 1.542 Å, corresponding to the weighted average of the Cu Kα₁ and Kα₂ transitions. The diffraction pattern was acquired using a two-dimensional x-ray detector at an angle of 350 and integrated in the azimuthal direction. X-ray reflections from multiple families of planes appear in FIG. 4 and are consistent with the formation of nanocrystals with a polycrystalline distribution of the orientation of the SrTiO₃ nanocrystals. The angles and indices of the reflections from SrTiO₃ are indicated in FIG. 4.

A model based on Ostwald ripening of the ensemble of nanocrystals was developed to interpret the time dependence of the mean radius and the area density. The model assumed that nanocrystals are in equilibrium with the adatom concentration in their immediate environment during heating. The model further assumed that nanocrystals are flat and circular, that the concentration of diffusing species far from each nanocrystal is in equilibrium with nanocrystals of the mean radius, that the primary mechanism for material redistribution is surface diffusion, that the diffusion equation can be solved under quasi-steady-state conditions, and that no new nanocrystals nucleate during the ripening process. With these assumptions, nanocrystals with radii at the large-radius end of the radius distribution continuously grow at the expense of smaller ones. The growth arises because there is a relatively high contribution of surface energy to the free energy of smaller nanocrystals and thus a higher-than equilibrium concentration of adatoms near small nanocrystals. Larger nanocrystals have a lower free energy per volume and grow due to the net flux of adatoms to their perimeters. (R. C. Desai and R. Kapral, Dynamics of Self-Organized and Self-Assembled Structures (Cambridge University Press, 2009) pp. 50-59; T. M. Rogers and R. C. Desai, Phys. Rev. B 39, 11956-11964 (1989).)

The two-dimensional Ostwald ripening model has been solved self consistently using a series of iterative numerical studies. (Rogers and Desai, 1989; J. A. Marqusee, J. Chem. Phys. 81, 976-981 (1984).) This Example considers the long-timescale limit appropriate for the ripening of large islands. In this limit, the mean radius was expected to scale as tⁿ with n to be ⅓, similar to the Lifshitz-Slyozov growth law in three dimensions. The area density of nanocrystals was expected to be proportional to t^{-2/3}.

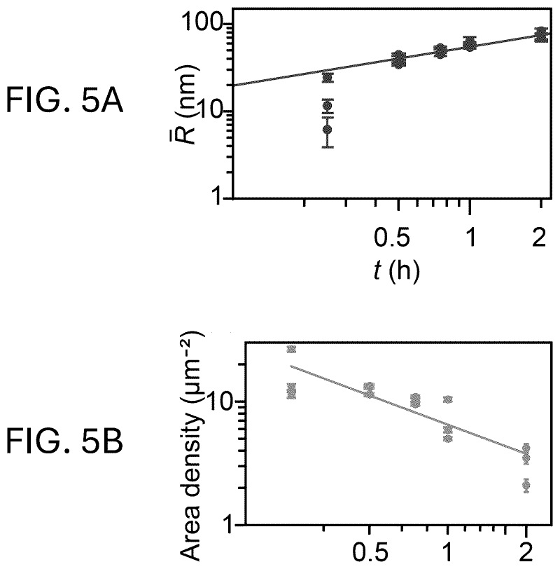

FIG. 5A shows a fit of a power-law dependence of the mean radius on time to the experimental results, giving an exponent 0.29. A relatively large disagreement between the experiment and model in FIG. 5A occurred at the earliest time, 15 min. The poor agreement at early times may have arisen because the experimental heating rate and thermal equilibration time were not included in t, such that the samples at early times may not have spent the nominal time at the processing temperature.

FIG. 5B shows the area density as a function of heating time. The slope of the power law fit in FIG. 5B is −0.78. The near agreement in alignment of the observed slope with the theoretical prediction shows agreement between the predictions of the Ostwald ripening model and the experimental results, confirming that the SrTiO₃ nanocrystals on SiO₂/Si substrates evolved following the assumptions underpinning the model.

The mean radii and area density of SrTiO₃ nanocrystals on an SiO₂/Si substrate have time dependence consistent with Ostwald ripening in two dimensions. This shows that Ostwald ripening accurately predicts the mean radius allows deposition and heating parameters to be selected to produce a predicted distribution of nanocrystals. This Example confirms the model's applicability, suggesting it as a practical tool for creating and optimizing two-dimensional nanocrystal seeds. The nucleation and ripening of nanocrystals offer a way to produce controlled distributions of nanocrystals on SiO₂/Si, fused silica, or other non-epitaxial substrates. Complex oxide films compatible with SrTiO₃ can grow on SiO₂/Si substrates with nanocrystals as nucleating sites, and properties can be tuned using these parameters.

Example 2: This Example illustrates the synthesis of crystalline thin films from films of their corresponding amorphous complex oxides. The amorphous films are sputter deposited without the use of a mask and have a uniform thickness.

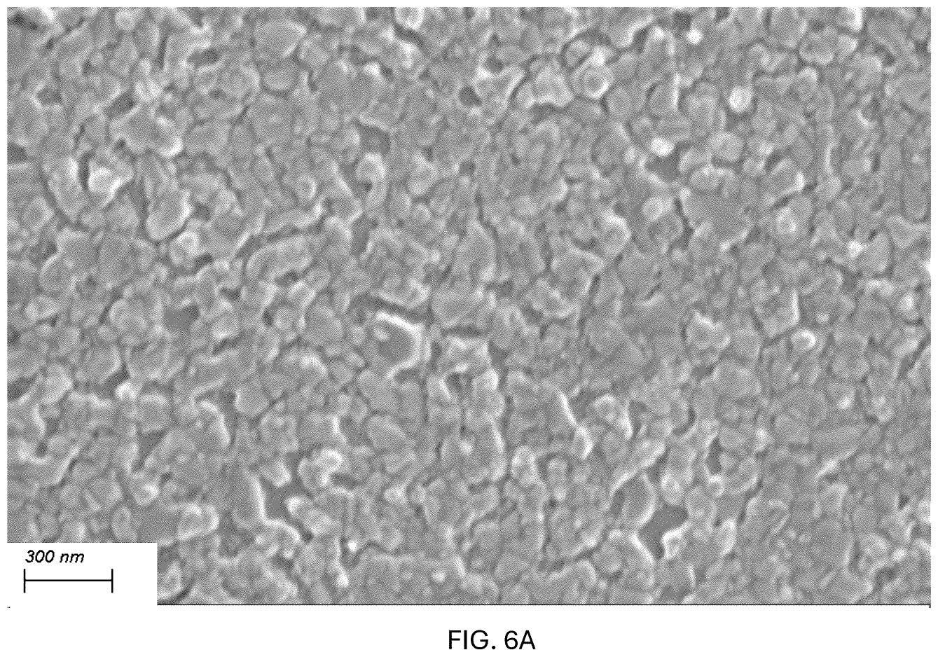

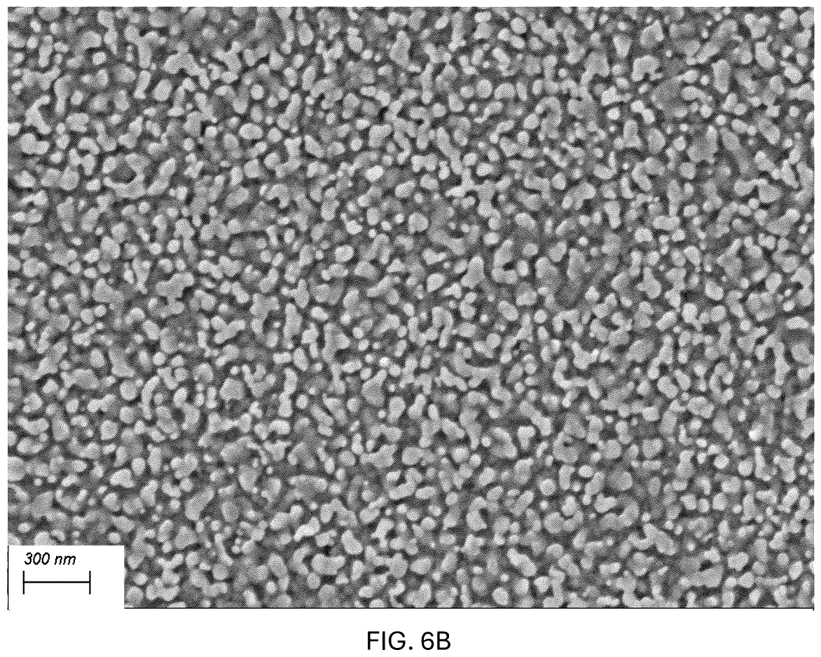

FIG. 6A and FIG. 6B show SEM micrographs of crystallized SrVO₃ on Si and fused quartz substrates, respectively. SrTiO₃ nanocrystal seeds were formed on these substrates before the deposition of an amorphous SrVO₃ film using the methods described above. The amorphous SrVO₃ film was deposited by RF sputtering using a gas mixture of argon (95%) and hydrogen (5%) at a gas pressure of 30 mtorr. The thickness of the amorphous SrVO₃ films shown in FIG. 6A and FIG. 6B were 28 nm and 67 nm respectively. The deposited amorphous SrVO₃ film was then annealed in furnace at ambient pressure in the same reducing gas mixture used for the deposition. The amorphous films were heated at 700° C. for a duration of 6 hr. The samples were characterized using the SEM equipped with an in-lens secondary electron detector operated at an accelerating voltage of 3 kV.

Unless otherwise indicated, any temperature- and/or pressure-dependent quantitative values disclosed herein refer to those values at room temperature (23° C.) and/or standard atmospheric pressure (1 atm).

The word “illustrative” is used herein to mean serving as an example, instance, or illustration. Any aspect or design described herein as “illustrative” is not necessarily to be construed as preferred or advantageous over other aspects or designs. Further, for the purposes of this disclosure and unless otherwise specified, “a” or “an” means “one or more.”

The foregoing description of illustrative embodiments of the invention has been presented for purposes of illustration and of description. It is not intended to be exhaustive or to limit the invention to the precise form disclosed, and modifications and variations are possible considering the above teachings or may be acquired from practice of the invention. The embodiments were chosen and described to explain the principles of the invention and as practical applications of the invention to enable one skilled in the art to utilize the invention in various embodiments and with various modifications as suited to the particular use contemplated. It is intended that the scope of the invention be defined by the claims appended hereto and their equivalents.

What is claimed is:

1. A transparent conducting perovskite oxide film comprising:
a substrate;
a plurality of crystalline perovskite oxide seeds on a surface of the substrate; and
a crystalline film of a transparent conducting perovskite oxide on the surface of the substrate between the crystalline perovskite oxide seeds, wherein:
the transparent conducting perovskite oxide is SrNbO₃ and the perovskite oxide of the crystalline perovskite oxide seeds is BaTiO₃; or
the transparent conducting perovskite oxide is BaSnO₃ and the perovskite oxide of the crystalline perovskite oxide seeds is CaZrO₃ or BaTiO₃; or
the transparent conducting perovskite oxide is Sr-doped LaCrO₃ and the perovskite oxide of the crystalline perovskite oxide seeds is NdAlO₃, SmAlO₃, PrAlO₃, KTaO₃, or SrTiO₃.

2. The transparent conducting perovskite oxide film of claim 1, wherein the transparent conducting perovskite oxide is SrVO₃ and the perovskite oxide of the crystalline perovskite oxide seeds is Ce:YAP.

3. The transparent conducting perovskite oxide film of claim 2, wherein the substrate is borosilicate glass.

4. The transparent conducting perovskite oxide film of claim 1, wherein the transparent conducting perovskite oxide is BaSnO₃ and the perovskite oxide of the crystalline perovskite oxide seeds is CaZrO₃.

5. The transparent conducting perovskite film of claim 4, wherein the substrate is borosilicate glass.

6. The transparent conducting perovskite oxide film of claim 1, wherein the transparent conducting perovskite oxide is SrNbO₃ and the perovskite oxide of the crystalline perovskite oxide seeds is BaTiO₃.

7. The transparent conducting perovskite oxide film of claim 1, wherein the transparent conducting perovskite oxide is BaSnO₃ and the perovskite oxide of the crystalline perovskite oxide seeds is BaTiO₃.

8. The transparent conducting perovskite oxide film of claim 1, wherein the transparent conducting perovskite oxide is Sr-doped LaCrO₃ and the perovskite oxide of the crystalline perovskite oxide seeds is NdAlO₃.

9. The transparent conducting perovskite oxide film of claim 1, wherein the transparent conducting perovskite oxide is Sr-doped LaCrO₃ and the perovskite oxide of the crystalline perovskite oxide seeds is SmAlO₃.

10. The transparent conducting perovskite oxide film of claim 1, wherein the transparent conducting perovskite oxide is Sr-doped LaCrO₃ and the perovskite oxide of the crystalline perovskite oxide seeds is PrAlO₃.

11. The transparent conducting perovskite oxide film of claim 1, wherein the transparent conducting perovskite oxide is Sr-doped LaCrO₃ and the perovskite oxide of the crystalline perovskite oxide seeds is KTaO₃.

12. The transparent conducting perovskite oxide film of claim 1, wherein the transparent conducting perovskite oxide is Sr-doped LaCrO₃ and the perovskite oxide of the crystalline perovskite oxide seeds is SrTiO₃.

13. A transparent conducting perovskite oxide film comprising:
a substrate composed of a substrate material;
a plurality of crystalline perovskite oxide seeds on a surface of the substrate, wherein a coefficient of thermal expansion of the substrate material differs from a coefficient of thermal expansion of the perovskite oxide of the perovskite oxide seeds by no more 50%; and
a crystalline film of a transparent conducting perovskite oxide on the surface of the substrate between the crystalline perovskite oxide seeds.

14. The transparent conducting perovskite oxide of claim 13, wherein the crystalline perovskite oxide seeds are free of edge-curling.

15. The transparent conducting perovskite oxide film of claim 14, wherein the crystalline perovskite oxide seeds have a thickness of no greater than 4 nm.

16. The transparent conducting perovskite oxide of claim 13, wherein:
the substrate material is borosilicate glass; and
the perovskite oxide of the perovskite oxide seeds is CaZrO₃.

17. The transparent conducting perovskite oxide of claim 13, wherein:
the substrate material is borosilicate glass; and
the perovskite oxide of the perovskite oxide seeds is Ce:YAP.

18. The transparent conducting perovskite oxide of claim 13, wherein the perovskite oxide of the perovskite oxide seed is a complex alloy perovskite oxide.

19. The transparent conducting perovskite oxide of claim 14, wherein the complex alloy complex oxide is a (La,Sr)(Co,Fe)O₃ perovskite oxide or a Ca(Zr, Hf, Ti)O₃ perovskite oxide.

20. A transparent conducting perovskite oxide film comprising:
a substrate composed of a substrate material;
a plurality of crystalline complex alloy perovskite oxide seeds on a surface of the substrate; and
a crystalline film of a transparent conducting perovskite oxide on the surface of the substrate between the crystalline complex alloy perovskite oxide seeds, wherein a lattice constant of the crystalline complex alloy perovskite oxide and a lattice constant of the transparent conducting perovskite oxide differ by less than 0.1 Å.
